(19) United States
(12) Patent Application Publication
(10) Pub. No.: US 2022/0277932 A1
(43) Pub. Date: Sep. 1, 2022

(54) PLASMA PROCESSING DEVICE

(71) Applicant: TOKYO ELECTRON LIMITED, Tokyo (JP)

(72) Inventor: Jun YAMAWAKU, Yamanashi (JP)

(21) Appl. No.: 17/632,056

(22) PCT Filed: Jul. 27, 2020
(86) PCT No.: PCT/JP2020/028627

§ 371 Date: Feb. 1, 2022

(30) Foreign Application Priority Data
Aug. 6, 2019 (JP) 2019-144557

(51) Int. Cl. H01J 37/32; C23C 16/505

(52) U.S. Cl. CPC H01J 37/3211; H01J 37/32651; C23C 16/505

(57) ABSTRACT

There is provided a plasma processing device. The plasma processing device comprises: a chamber accommodating a stage on which a substrate is placed; an antenna disposed outside the chamber; a dielectric window disposed between the chamber and the antenna; a gas supply unit configured to supply a process gas into the chamber; a power supply unit configured to supply high-frequency power to the antenna to supply high-frequency waves into the chamber through the dielectric window and generate plasma from the process gas in the chamber; an electron generation unit configured to generate electrons in the chamber by excitation of the process gas supplied into the chamber; and a control device configured to control the power supply unit so as to supply the high-frequency power to the antenna simultaneously with the start of the excitation of the process gas by the electron generation unit or after the excitation of the process gas by the electron generation unit is started.

### TECHNICAL FIELD

The present disclosure relates to a plasma processing device.

### BACKGROUND

As a processing device for performing one of semiconductor manufacturing processes, a plasma processing device for performing etching, film formation or the like using plasma of a process gas is known. In this plasma processing device, an inductively coupled plasma (ICP) or a capacitively coupled plasma (CCP) is used. ICP has a higher electron density compared to CCP, and thus has an excellent gas dissociation property. Therefore, the plasma processing device may perform processing using ICP.

### PRIOR ART DOCUMENTS

### Patent Documents

Patent Document 1: Japanese Laid-open Patent Publication No. 2010-153274

### SUMMARY

### Problems to Be Resolved by the Invention

The present disclosure provides a plasma processing device capable of igniting ICP mode plasma at a higher speed.

### Means of Solving the Problems

In accordance with an aspect of the present disclosure, there is provided a plasma processing device provided with a chamber, an antenna, a dielectric window, a gas supply unit, a power supply unit, and electron generation unit, and a control device. A stage for mounting a substrate thereon is accommodated inside the chamber. The antenna is disposed outside the chamber. The dielectric window is disposed between the chamber and the antenna. The gas supply unit supplies a process gas into the chamber. The power supply unit supplies high-frequency power to the antenna in order to supply high-frequency waves into the chamber and generate plasma from the process gas in the chamber. The electron generation unit generates electrons inside the chamber by exciting the process gas supplied into the chamber. The control device controls the power supply unit so as to supply the high-frequency power to the antenna simultaneously with the start of the excitation of the process gas by the electron generation unit or after the excitation of the process gas by the electron generation unit is started.

### Effect of the Invention

In accordance with various aspects and embodiments of the present disclosure, it is possible to ignite ICP mode plasma at a higher speed.

### BRIEF DESCRIPTION OF THE DRAWINGS

FIG. 1 is a schematic cross-sectional view showing an example of a plasma processing device according to a first embodiment of the present disclosure.

FIG. 2 shows an example of changes in power supplied to an antenna and reflected power in a comparative example.

FIG. 3 shows an example of an electron density in various discharge phenomena.

FIG. 4 is a flowchart showing an example of a film forming process.

FIG. 5 is a schematic cross-sectional view showing an example of a plasma processing device according to a second embodiment of the present disclosure.

FIG. 6 is a schematic cross-sectional view showing an example of a plasma processing device according to a third embodiment of the present disclosure.

FIG. 7 shows another example of a DC voltage application method.

### DETAILED DESCRIPTION

Hereinafter, embodiments of a plasma processing device of the present disclosure will be described in detail with reference to the accompanying drawings. The plasma processing device of the present disclosure is not limited by the following embodiments.

In a plasma processing device using ICP, first, plasma is generated in a CCP mode in order to ignite ICP. Then, when electrons in the plasma generated in the CCP mode are replenished by an induced magnetic field generated in the chamber by an antenna, the plasma is shifted to an ICP mode.

In order to allow the plasma to be shifted to the ICP mode, it is necessary to generate a sufficient amount of electrons in the CCP mode plasma. Therefore, in the plasma processing device, it is necessary to perform matching between a high-frequency power supply and the antenna in the CCP mode as well as the ICP mode.

In performing matching between the high-frequency power supply and the antenna, for example, it is necessary to sequentially change a capacitance of a variable capacitor such that a magnitude of reflected waves with respect to power supplied from the high-frequency power supply to the antenna becomes small. Therefore, a certain period of time is required to perform matching between the high-frequency power supply and the antenna. If the matching between the high-frequency power supply and the antenna is required in the CCP mode as well as the ICP mode, time is required to ignite the ICP mode plasma. Hence, it is difficult to use the ICP mode plasma in a process of repeating short plasma processing such as plasma enhanced-atomic layer deposition (PE-ALD).

Therefore, the present disclosure provides a technique capable of igniting ICP mode plasma at a higher speed.

### First Embodiment

<Configuration of Plasma Processing Device 1>

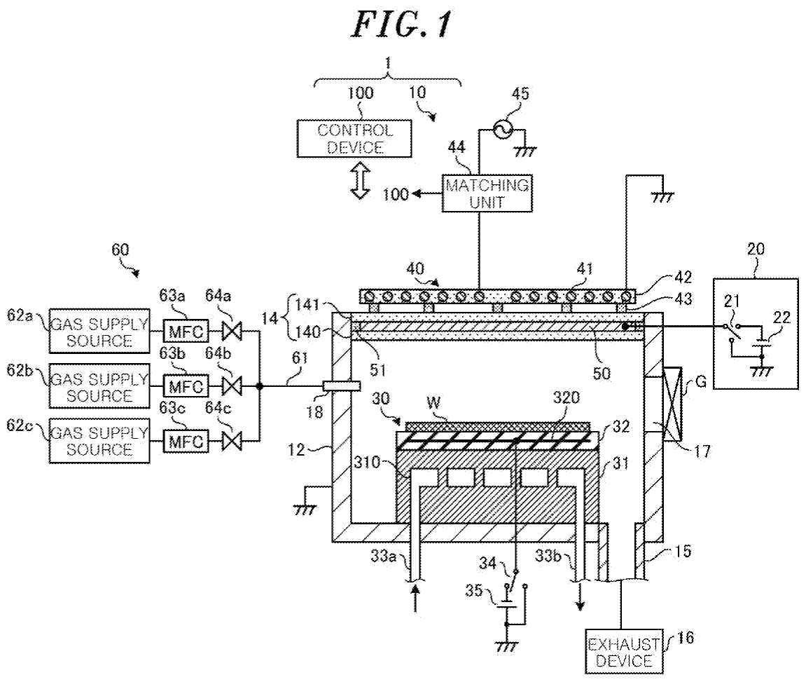

FIG. 1 is a schematic cross-sectional view showing an example of a plasma processing device 1 according to a first embodiment of the present disclosure. The plasma processing device 1 uses PE-ALD to form a desired film (e.g., a silicon nitride film) on a wafer W as an example of a substrate. The plasma processing device 1 uses ICP as a plasma source.

The plasma processing device 1 includes a main body 10 and a control device 100. The main body 10 includes a chamber 12 having a bottom portion and an upper opening. An upper portion of the chamber 12 is blocked by a dielectric window 14. The chamber 12 is made of a metal such as aluminum or the like, and thermal spray coating made of a plasma resistant material is formed on an inner wall of the chamber 12. The chamber 12 is grounded.

The dielectric window 14 has a first dielectric window 140 and a second dielectric window 141. A Faraday shield 50 made of a metal such as aluminum or the like is disposed between the first dielectric window 140 and the second dielectric window 141. An insulating member 51 made of an insulator is disposed between the Faraday shield 50 and a sidewall of the chamber 12. The Faraday shield 50 and the chamber 12 are electrically insulated from each other. A DC voltage supply part 20 is connected to the Faraday shield 50. The DC voltage supply part 20 has a switch 21 and a DC power supply 22.

After a gas is supplied into the chamber 12, the control device 100 controls the switch 21 to supply a DC voltage from the DC power supply 22 to the Faraday shield 50. Accordingly, the DC voltage is applied to the gas in the chamber 12 through the Faraday shield 50, and DC discharge is generated in the chamber 12. Electrons are generated in the chamber 12 by the DC discharge. The DC discharge is generated for about several tens to several hundreds of μs, for example, after the DC voltage is applied to the gas in the chamber 12 through the Faraday shield 50. The DC voltage supply part 20 is an example of an electron generation unit. In the present embodiment, the DC power supply 22 applies a negative DC voltage to the Faraday shield 50 through the switch 21. However, in another example, the DC power supply 22 may apply a positive DC voltage to the Faraday shield 50 through the switch 21.

A stage 30 for placing a wafer W thereon is accommodated in the chamber 12. The stage 30 includes a base 31 and an electrostatic chuck 32. The base 31 is made of a conductive metal such as aluminum or the like, and is supported at the bottom portion of the chamber 12. The base 31 is grounded through the bottom portion of the chamber 12.

The electrostatic chuck 32 is disposed on the base 31. The electrostatic chuck 32 is made of an insulator and has therein an electrode 320. A DC power supply 35 is connected to the electrode 320 through a switch 34. A Coulomb force is generated on a top surface of the electrostatic chuck 32 by the DC voltage applied from the DC power supply 35 to the electrode 320 through the switch 34, and the wafer W is attracted and held on the upper surface of the electrostatic chuck 32 by the Coulomb force.

A heater (not shown) is built in the electrostatic chuck 32. An AC voltage is applied from an AC power supply (not shown) to the heater. The power supply to the electrostatic chuck 32 and the heater is controlled by the control device 100. Further, an edge ring (not shown) is disposed on the upper surface of the electrostatic chuck 32 corresponding to a position of an outer periphery of the wafer W attracted and held on the electrostatic chuck 32. The edge ring is made of, e.g., single crystal silicon. The edge ring may also be referred to as “focus ring.”

A flow path 310 through which a coolant flows is formed in the base 31. A temperature-controlled coolant is supplied from a chiller unit (not shown) to the flow path 310 through lines 33a and 33b and circulated therein. A temperature of the wafer W on the electrostatic chuck 32 is adjusted to a desired temperature by performing cooling using the coolant circulating in the flow path 310 and heating using the heater in the electrostatic chuck 32.

A supply port 18 for supplying a gas into the chamber is disposed on the sidewall of the chamber 12. A gas supply unit 60 is connected to the supply port 18 through a line 61. The gas supply unit 60 includes gas supply sources 62a to 62c, mass flow controllers (MFCs) 63a to 63c, and valves 64a to 64c. The MFCs 63a to 63c and the valves 64a to 64c are controlled by the control device 100.

The gas supply source 62a is a source of a precursor gas. The gas supply source 62b is a supply source of a reaction gas. The gas supply source 62c is a source of an inert gas. In the present embodiment, the precursor gas is, e.g., dichlorosilane (DCS) gas; the reaction gas is, e.g., ammonia or nitrogen gas; and the inert gas is, e.g., argon gas. The reaction gas is an example of the process gas.

The MFC 63a controls a flow rate of the precursor gas supplied from the gas supply source 62a, and supplies the precursor gas whose flow rate is controlled into the chamber 12 through the valve 64a and the line 61. The MFC 63b controls a flow rate of the reaction gas supplied from the gas supply source 62b, and supplies the reaction gas whose flow rate is controlled into the chamber 12 through the valve 64b and the line 61. The MFC 63c controls a flow rate of the inert gas supplied from the gas supply source 62c, and supplies the inert gas whose flow rate is controlled into the chamber 12 through the valve 64c and the line 61.

An exhaust device 16 is connected to the bottom portion of the chamber 12 through an exhaust line 15. The exhaust device 16 has a vacuum pump (not shown), and a pressure in the chamber 12 can be decreased to a desired vacuum level. Further, an opening 17 through which the wafer W is loaded and unloaded is formed on the sidewall of the chamber 12. The opening 17 is opened and closed by a gate valve G.

The antenna 40 is disposed above the dielectric window 14. The antenna 40 has a lead wire 41 made of a conductive material such as copper or the like. In the present embodiment, the lead wire 41 is held by a holder 42 made of an insulator to maintain a flat coil shape. The antenna 40 is separated from the dielectric window 14 by a spacer 43 made of an insulator.

A high-frequency power supply 45 is connected to one end of the lead wire 41 through a matching unit 44. The other end of the lead wire 41 is grounded. The high-frequency power supply 45 supplies high-frequency power for plasma generation, e.g., high-frequency power having a frequency of 27 MHz to the antenna 40 through the matching unit 44. The frequency and magnitude of the high-frequency power supplied from the high-frequency power supply 45 to the antenna 40 are controlled by the control device 100. The matching unit 44 matches an output impedance of the high-frequency power supply 45 with an input impedance on a load (the antenna 40) side. Further, the matching unit 44 outputs to the control device 100 information indicating the magnitude of reflected power with respect to the high-frequency power supplied from the high-frequency power supply 45 to the antenna 40. The matching unit 44 is controlled by the control device 100. The high-frequency power supply 45 is an example of a power supply unit.

The antenna 40 generates a high-frequency magnetic field in the chamber 12 through the dielectric window 14 by the high-frequency power supplied from the high-frequency power supply 45. A high-frequency induced electric field is generated in the chamber 12 by the high-frequency magnetic field generated in the chamber 12. Due to the induced electric field generated in the chamber 12, the process gas supplied into the chamber 12 is excited, and plasma of the process gas is generated in the chamber 12. Then, the wafer W on the electrostatic chuck 32 is subjected to processing such as film formation or the like by ions or active species contained in the plasma.

The antenna 40 of the present embodiment is a loop antenna. However, in another embodiment, the antenna 40 may be a resonance antenna, a dipole antenna, or the like. Further, in the present embodiment, one antenna 40 is disposed on the dielectric window 14. However, in another embodiment, a plurality of antennas 40 may be disposed on the dielectric window 14. Further, the antenna 40 may be disposed around the chamber 12.

The control device 100 includes a memory, a processor, and an input/output interface. The memory stores a program executed by the processor and a recipe including conditions for each process, and the like. The processor executes the program read from the memory, and controls individual components of the main body 10 through the input/output interface based on the recipe stored in the memory.

<Plasma Mode Transition>

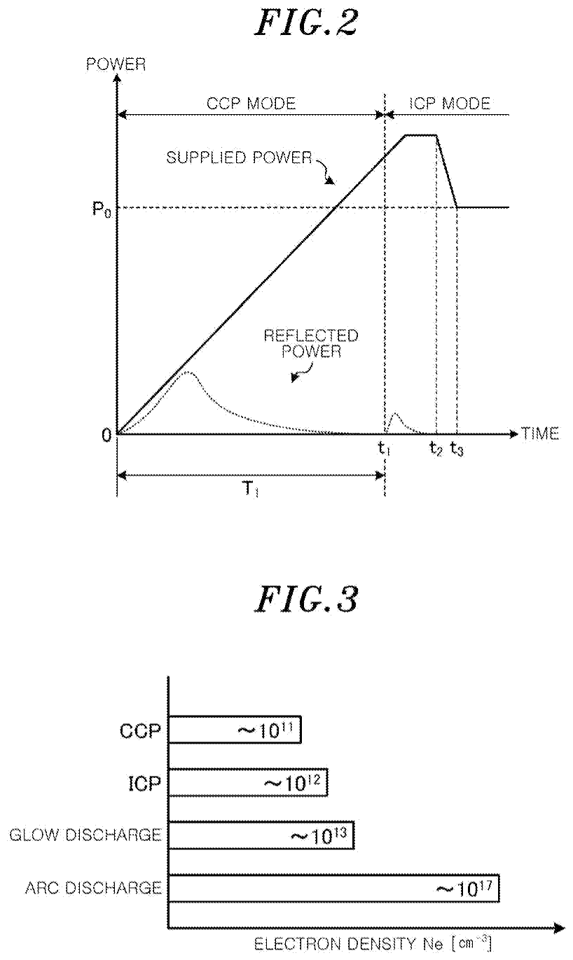

In the plasma processing device 1 illustrated in FIG. 1, plasma processing is performed using ICP. In the present embodiment, the DC voltage is applied to the reaction gas through the Faraday shield 50 in the process of igniting the ICP mode plasma. Here, the plasma mode transition in the case where the DC voltage is not applied to the reaction gas through the Faraday shield 50 in the process of igniting the ICP mode plasma, i.e., in the case where the Faraday shield 50 is grounded, will be described as a comparative example. FIG. 2 shows an example of changes in power supplied to the antenna 40 and reflected power in the comparative example.

In the comparative example, first, plasma is generated in the CCP mode in the chamber 12, as shown in FIG. 2, for example. In the CCP mode, the control device 100 controls the matching unit 44 and the high-frequency power supply 45 such that the reflected power becomes small while gradually increasing the power supplied to the antenna 40.

Then, the plasma is ignited in the CCP mode at timing t₁ in which sufficient power is supplied from the antenna 40 and the reflected power becomes lower than or equal to a predetermined value. When the plasma is ignited in the CCP mode, a sufficient amount of electrons are generated in the chamber 12. When the electrons generated by the CCP mode plasma are replenished by the induced magnetic field generated in the chamber by the antenna 40, the mode of the plasma is shifted from the CCP mode to the ICP mode. In the example of FIG. 2, a period of time T₁ from the supply of the high-frequency power to the antenna 40 to the plasma mode transition to the ICP mode is, e.g., about several tens of milliseconds.

Since the impedance of the CCP mode plasma is different from the impedance of the ICP mode plasma, the reflected power increases again after the plasma mode transition to the ICP mode. The control device 100 controls the matching unit 44 such that the reflected power becomes small in the ICP mode. Then, the ICP mode plasma is ignited at timing t₂ in which the reflected power becomes lower than or equal to the predetermined value again. Then, the control device 100 adjusts the power supplied to the antenna 40, and sets power supplied to the antenna 40 at timing t₃ to power P₀.

Here, in the comparative example, it is necessary to generate CCP mode plasma even when ICP mode plasma is generated. Therefore, it is necessary to match the impedance between the CCP mode plasma and the high-frequency power supply 45. Since a certain period of time is required to adjust the impedance using the matching unit 44, time required to ignite the ICP mode plasma increases. In PE-ALD, plasma processing time in one cycle of ALD is several tens of milliseconds, which is short. Therefore, if the time T₁ required to ignite the CCP mode plasma is, e.g., about several tens of milliseconds, it is difficult to use ICP as a plasma source of PE-ALD in the comparative example.

Therefore, in the present embodiment, a sufficient amount of electrons are generated in the chamber 12 before high-frequency plasma is generated in the chamber 12. Accordingly, the period of the CCP mode can be eliminated, and the ICP mode plasma can be ignited within a short period of time.

In the present embodiment, after the reaction gas is supplied into the chamber 12, DC discharge is generated in the chamber 12 by supplying a DC voltage from the DC power supply 22 to the Faraday shield 50 through the switch 21. Accordingly, a sufficient amount of electrons are quickly generated in the chamber 12, and the ICP mode plasma can be easily ignited without the CCP mode. The DC voltage may be supplied to the Faraday shield 50 before the supply of the high-frequency power to the antenna 40, or may be supplied simultaneously with the supply of the high-frequency power to the antenna 40.

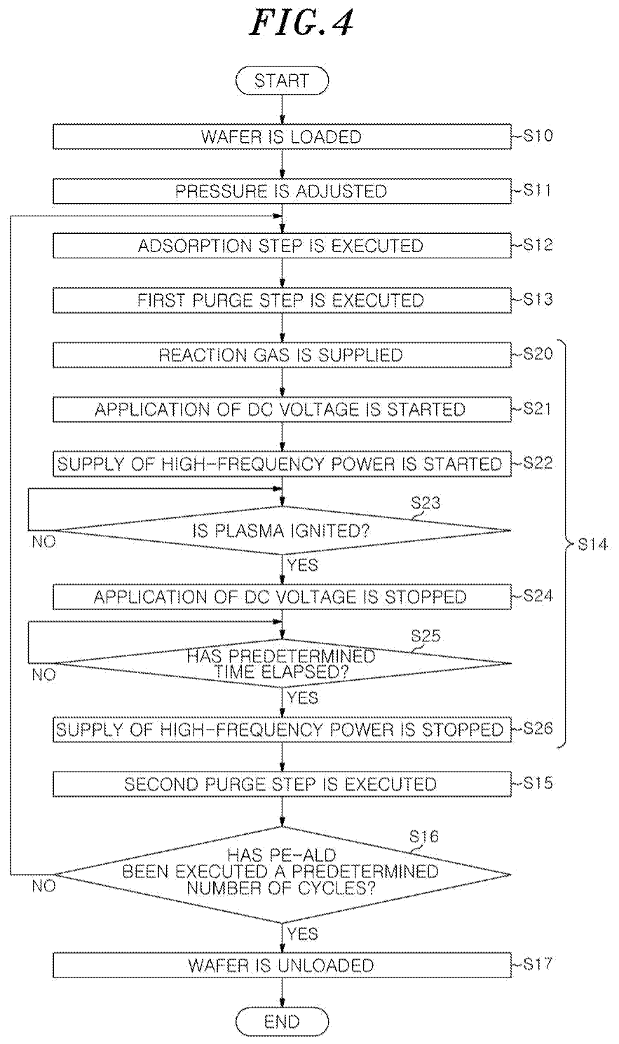

FIG. 3 shows an example of an electron density in various discharge phenomena. For example, as shown in FIG. 3, the maximum electron density of the CCP mode plasma is about 10¹¹ [cm⁻³], and the maximum electron density of the ICP mode plasma is about 10¹² [cm⁻³]. Therefore, in order to shift the plasma mode from the CCP mode to the ICP mode, it is necessary to supply high power and generate plasma having a high electron density in the CCP mode.

On the other hand, the electron density of the DC discharge such as glow discharge, arc discharge, or the like is higher than the electron density of the ICP mode plasma. Thus, if DC discharge is generated before the generation of the high-frequency plasma is started, an electron density higher than or equal to that of the ICP mode plasma is realized, and the ICP mode plasma can be ignited quickly. The arc discharge is not preferable because it damages the wafer W, the components in the chamber 12, and the like. Therefore, the DC discharge generated before the start of generation of the high-frequency plasma is preferably glow discharge.

Further, the plasma processing device 1 is designed to generate the ICP mode plasma, and the plasma generation in the CCP mode is suppressed by the Faraday shield 50 that is grounded. Therefore, it is difficult to ignite the CCP mode plasma in the chamber 12. Hence, in order to ignite the CCP mode plasma, it is necessary to supply power higher than the power supplied in the ICP mode to the antenna 40. In a process such as film formation or the like having a higher pressure than that in an etching process, the power required for ignition is further higher. Therefore, power consumption and heat generation of components increase.

On the other hand, in the present embodiment, a sufficient amount of electrons are generated in the chamber 12 before the generation of the high-frequency plasma is started in the chamber 12, so that the period of the CCP mode is eliminated. Therefore, it is not necessary to supply higher power to ignite the CCP mode plasma. Accordingly, it is possible to reduce power consumption and heat generation of components.

Further, in the comparative example, even when the ICP mode plasma is generated, it is necessary to generate the CCP mode plasma, and match the impedance between the CCP mode plasma and the high-frequency power supply 45. Since the impedance of the ICP mode plasma and the impedance of the CCP mode plasma are different, the matching unit 44 requires a wide matching range. Accordingly, a circuit scale of the matching unit 44 becomes large, and the device is scaled up.

On the other hand, in the present embodiment, since a sufficient amount of electrons are generated in the chamber before the generation of the high-frequency plasma is started in the chamber 12, the period of the CCP mode is eliminated. Thus, it is unnecessary to match the impedance between the CCP mode plasma and the high-frequency power supply 45. Accordingly, the circuit scale of the matching unit 44 can be reduced, and the device can be scaled down.

<Film Formation>

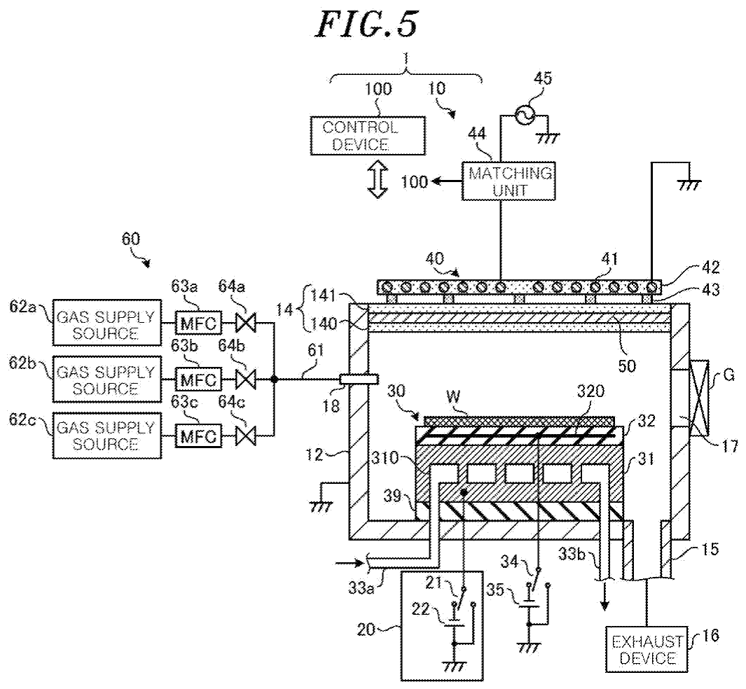

FIG. 4 is a flowchart showing an example of film formation. The film formation described in FIG. 4 is realized mainly by operating the main body 10 under the control of the control device 100.

First, the wafer W is loaded into the chamber 12 (S10). In step S10, the gate valve G is opened, and the wafer W is loaded into the chamber 12 by a transfer arm (not shown) and placed on the electrostatic chuck 32. Then, the gate valve G is closed. Then, a DC voltage is supplied from the DC power supply 35 to the electrode 320 through the switch 34, and the wafer W is attracted and held on the upper surface of the electrostatic chuck 32.

Next, the pressure in the chamber 12 is adjusted (S11). In step S11, the gas in the chamber 12 is exhausted by the exhaust device 16. Then, the valve 64c is opened, and the inert gas whose flow rate is adjusted by the MFC 63c is supplied into the chamber 12. The control device 100 adjusts the pressure in the chamber 12 by adjusting an opening degree of an auto pressure control (APC) valve (not shown) disposed between the chamber 12 and the exhaust device 16. Then, the valve 64c is closed.

Next, a PE-ALD cycle (steps S12 to S16) is executed. In the PE-ALD cycle, first, an adsorption step is executed (S12). In step S12, the valve 64a is opened and the precursor gas whose flow rate is adjusted by the MFC 63a is supplied into the chamber 12. Accordingly, molecules of the precursor gas are adsorbed on the surface of the wafer W. Then, the valve 64a is closed.

Next, a first purge step is executed (S13). In step S13, the valve 64c is opened and the inert gas whose flow rate is adjusted by the MFC63c is supplied into the chamber 12. Accordingly, molecules of the precursor gas that are excessively adsorbed on the surface of the wafer W are removed.

Next, a reaction step is executed (S14). In step S14, the processes of steps S20 to S26 are executed. In the reaction step, first, the reaction gas is supplied into the chamber 12 (S20). In step S20, the valve 64b is opened, and the reaction gas whose flow rate is adjusted by the MFC63b and the inert gas whose flow rate is adjusted by the MFC63c are supplied into the chamber 12.

Next, the application of the DC voltage is started (S21). In step S21, the control device 100 controls the switch 21 to connect the Faraday shield 50 and the DC power supply 22, so that the DC voltage from the DC power supply 22 is applied to the Faraday shield 50. Then, a DC voltage is applied to the reaction gas through the Faraday shield 50, and DC discharge is generated in the chamber 12. Due to the generation of DC discharge, electrons are generated in the chamber 12. The DC discharge is generated for about several tens to several hundreds of its, for example, after the DC voltage is applied to the reaction gas through the Faraday shield 50. Therefore, the amount of electrons required for the plasma mode transition from the CCP mode to the ICP mode can be generated in the chamber 12 for about several tens to several hundreds of us after the DC voltage is applied to the reaction gas through the Faraday shield 50, for example.

Next, the supply of high-frequency power from the high-frequency power supply 45 to the antenna 40 is started (S22). Then, the control device 100 refers to the magnitude of the reflected power outputted from the matching unit 44, and controls the matching unit 44 such that the reflected power becomes small while gradually increasing the magnitude of the high-frequency power supplied from the high-frequency power supply 45 to the antenna 40. Due to the DC discharge in step S21, a sufficient amount of electrons are quickly generated in the chamber 12 and, thus, the ICP mode plasma is quickly generated in the chamber 12. In the example of FIG. 4, step S22 is executed after step S21. However, in another example, step S21 and step S22 may be executed at the same time.

Next, the control device 100 determines whether or not the plasma is ignited (S23). In step S23, the control device 100 determines whether or not the plasma is ignited by determining whether or not the magnitude of the reflected power outputted from the matching unit 44 is smaller than or equal to a predetermined threshold value. When the plasma is not ignited (S23: No), the control device 100 executes the process of step S23 again.

On the other hand, when the plasma is ignited (S23: Yes), the application of the DC voltage is stopped (S24). In step S24, the control device 100 stops the application of the DC voltage to the Faraday shield 50 by controlling the switch 21 such that the Faraday shield 50 is grounded. Accordingly, the DC discharge is stopped in the chamber 12. The plasma ignited in step S23 is the ICP mode plasma. Due to the ICP mode plasma, the molecules of the precursor gas adsorbed on the surface of the wafer W react with the active species contained in the plasma, and a target film is formed on the surface of the wafer W.

Next, the control device 100 determines whether or not a predetermined time has elapsed from the start of step S14 (S25). The predetermined time is the plasma processing time in PE-ALD, e.g., several tens of milliseconds. If the predetermined time has not elapsed (S25: No), the control device 100 executes the process of step S25 again. On the other hand, when the predetermined time has elapsed (S25: Yes), the supply of high-frequency power is stopped (S26). Then, the valve 64b is closed.

After the reaction step in step S14 is completed, a second purge step is executed (S15). In step S15, the inert gas whose flow rate is adjusted by the MFC63c is supplied into the chamber 12. Accordingly, the excessively supplied active species and the like are removed from the surface of the wafer W. Then, the valve 64c is closed.

Next, the control device 100 determines whether or not the PE-ALD has been executed a predetermined number of cycles (S16). If PE-ALD has not been executed the predetermined number of cycles (S16: No), the process of step S12 is executed again.

On the other hand, when PE-ALD has been executed the predetermined number of cycles (S16: Yes), the exhaust device 16 is stopped and the gate valve G is opened. Then, the wafer W after the film formation is transferred from the electrostatic chuck 32 to the outside of the chamber 12 by a transfer arm (not shown). Then, the film formation shown in this flowchart is completed.

As described in the first embodiment, the plasma processing device 1 of the present embodiment includes the chamber 12, the antenna 40, the dielectric window 14, the gas supply unit 60, the high-frequency power supply 45, the DC voltage supply part 20, and the control device 100. The chamber 12 accommodates the stage 30 for placing the wafer W thereon. The antenna 40 is disposed outside the chamber 12. The dielectric window 14 is disposed between the chamber 12 and the antenna 40. The gas supply unit 60 supplies the reaction gas into the chamber 12. The high-frequency power supply 45 supplies the high-frequency power to the antenna 40, thereby supplying the high-frequency waves to the chamber 12 through the dielectric window 14 and generating plasma from the reaction gas in the chamber 12. The DC voltage supply part 20 generates electrons in the chamber 12 by exciting the reaction gas supplied into the chamber 12. The control device 100 controls the high-frequency power supply 45 to supply the high-frequency power to the antenna 40 simultaneously with the start of the excitation of the reaction gas by the DC voltage supply part 20, or after the excitation of the reaction gas by the DC voltage supply part 20 is started. Accordingly, the ICP mode plasma can be ignited at a higher speed.

Further, in the above-described first embodiment, the DC voltage supply part 20 applies a DC voltage to the reaction gas supplied in the chamber 12 to generate DC discharge and generate electrons in the chamber 12. Accordingly, electrons can be quickly generated in the chamber 12.

Further, in the above-described first embodiment, the dielectric window 14 includes the first dielectric window 140 and the second dielectric window 141, and the Faraday shield 50 is disposed between the first dielectric window 140 and the second dielectric window 141. The DC voltage supply part 20 applies the DC voltage to the Faraday shield 50 to generate DC discharge in the chamber 12. Accordingly, the DC discharge can be easily generated in the chamber 12.

### Second Embodiment

In the above-described first embodiment, a DC voltage is applied to the reaction gas through the Faraday shield 50 to generate DC discharge in the chamber 12 to which the reaction gas is supplied. On the other hand, the present embodiment is different from the first embodiment in that a DC voltage is applied to the reaction gas through the base 31. Hereinafter, the differences between the present embodiment and the first embodiment will be mainly described.

FIG. 5 is a schematic cross-sectional view showing an example of a plasma processing device 1 according to the second embodiment of the present disclosure. The components in FIG. 5 denoted by like reference numerals as those in FIG. 1 indicate the same or similar functions as those of the components in FIG. 1 except the following characteristics and, thus, the description thereof will be omitted.

In the present embodiment, the base 31 is supported at the bottom portion of the chamber 12 via a support member 39 made of an insulator. The base 31 and the chamber 12 are electrically insulated by the support member 39.

Further, the DC voltage supply part 20 is connected to the base 31. After the gas is supplied into the chamber 12, the control device 100 controls the switch 21 to supply the DC voltage from the DC power supply 22 to the base 31. Accordingly, DC discharge is generated in the chamber 12, and electrons are generated in the chamber 12.

Also in this configuration, electrons can be generated in the chamber 12 by DC discharge, and the ICP mode plasma can be ignited at a higher speed.

### Third Embodiment

In the above-described first embodiment, by applying a DC voltage to the reaction gas through the Faraday shield 50, DC discharge is generated in the chamber 12 to which the reaction gas is supplied. On the other hand, the present embodiment is different from the first embodiment in that the DC voltage is applied to the reaction gas through the antenna 40 by superimposing the DC voltage on the high-frequency power. Hereinafter, the differences between the present embodiment and the first embodiment will be mainly described.

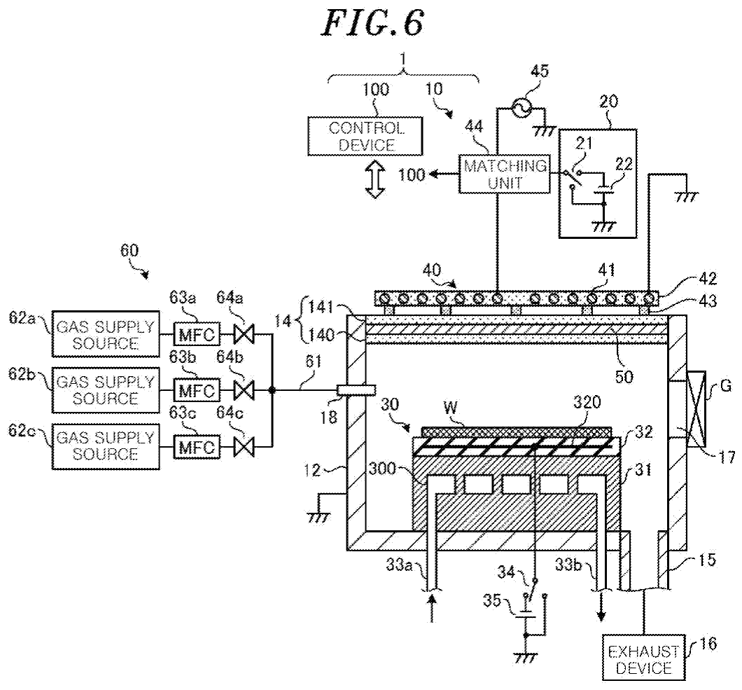

FIG. 6 is a schematic cross-sectional view showing an example of a plasma processing device 1 according to the third embodiment of the present disclosure. The components in FIG. 6 denoted by like reference numerals as those in FIG. 1 indicate the same or similar functions as those of the components in FIG. 1 except the following characteristics and, thus, the description thereof will be omitted.

In the present embodiment, the DC voltage supply part 20 is connected to the matching unit 44. The control device 100 controls the switch 21 to connect the matching unit 44 and the DC power supply 22 when DC discharge is generated in the chamber 12. Then, the control device 100 superimposes the DC voltage supplied from the DC power supply 22 through the switch 21 on the high-frequency power supplied from the high-frequency power supply 45, and supplies the DC voltage superimposed on the high-frequency power to the antenna 40. Due to the DC voltage superimposed on the high-frequency power and supplied to the antenna 40, DC discharge is generated in the chamber 12 to which the reaction gas is supplied, and electrons are generated in the chamber 12.

Also in this configuration, electrons can be generated in the chamber 12 by DC discharge, and the ICP mode plasma can be ignited at a higher speed.

(Other Applications)

The technique of the present disclosure is not limited to the above-described embodiments, and various modifications can be made within the scope of the gist thereof.

For example, in the above-described embodiments, in the reaction step, the DC voltage from the DC voltage supply part is continuously applied to the reaction gas until the plasma is ignited. However, the technique of the present disclosure is not limited thereto. For example, the DC voltage from the DC voltage supply part 20 may be intermittently applied to the reaction gas. In other words, the control device 100 may control the DC voltage supply part 20 to repeatedly apply the DC voltage to the reaction gas at predetermined time intervals until plasma is generated from the reaction gas in the chamber 12.

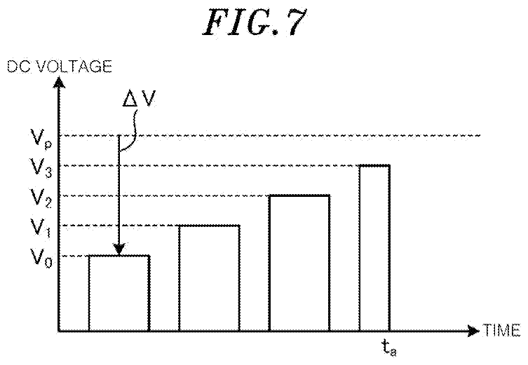

Further, in this case, the control device 100 may gradually change the DC voltage applied to the reaction gas from a low voltage to a high voltage, as shown in FIG. 7, for example. In other words, the control device 100 may control the DC voltage supply part 20 such that the magnitude of the DC voltage applied to the reaction gas gradually increases at predetermined time intervals until plasma is generated from the reaction gas in the chamber 12. In this case, a variable DC voltage source is used as the DC power supply 22.

FIG. 7 shows another example of a DC voltage application method. In the example of FIG. 7, the DC voltage applied to the reaction gas gradually increases from V₀ lower by a predetermined voltage ΔV than a DC voltage Vₚ at the time of previous plasma ignition to V₁, V₂, . . . . In the example of FIG. 7, the plasma is ignited at the timing tₐ. Accordingly, it is possible to ignite the ICP mode plasma with a lower voltage suitable for the condition of the chamber 12. Hence, the power consumed by the DC voltage supply part 20 can be reduced.

Here, in the film forming process, reaction by-products (so-called deposits) may be deposited on the inner wall of the chamber 12 or the components in the chamber 12. Therefore, when the PE-ALD cycle is repeated, the state in the chamber 12 may gradually change, and the magnitude of the DC voltage for igniting the ICP mode plasma may change. In the example of FIG. 7, the DC voltage applied to the reaction gas gradually increases from the voltage V₀ lower than the DC voltage Vₚ at the time of previous plasma ignition by the predetermined voltage ΔV. Accordingly, the ICP mode plasma can be ignited with a lower voltage, and the increase in the time required to ignite the ICP mode plasma can be suppressed.

Also in the first to third embodiments in which the DC voltage is continuously applied to the reaction gas, the DC voltage may be gradually increased from the voltage V₀ lower than the DC voltage Vₚ at the time of previous plasma ignition by the predetermined voltage ΔV.

In the above-described embodiments, the DC voltage supply part 20 is used as an example of the electron generation unit for generating electrons by exciting the reaction gas. However, the technique of the present disclosure is not limited thereto. The electron generation unit may be configured to excite the reaction gas and generate electrons by irradiating ultraviolet (UV) light to the reaction gas.

Further, in the above-described embodiments, the plasma processing device 1 for forming a predetermined film on the wafer W by PE-ALD has been described as an example. However, the technique of the present disclosure is not limited thereto. The technique of the present disclosure can be applied to a device for forming a film by plasma chemical vapor deposition (CVD) as long as it is a device for forming a film using ICP. Further, the technique of the present disclosure can be applied to an etching device, a cleaning device, or the like as long as it is a device for performing processing using ICP.

Further, it should be noted that the embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

### DESCRIPTION OF REFERENCE NUMERALS

G: gate valve
W: wafer
1: plasma processing device
10: main body
12: chamber
14: dielectric window
140: first dielectric window
141: second dielectric window
15: exhaust line
16: exhaust device
17: opening
18: supply port
20: DC voltage supply part
21: switch
22: DC power supply
30: stage
31: base
310: flow path
32: electrostatic chuck
320: electrode
33: line
34: switch
35: DC power supply
39: support member
40: antenna
41: lead wire
42: holder
43: spacer
44: matching unit
45: high-frequency power supply
50: Faraday shield
51: insulating member
60: gas supply unit
61: line
62: gas supply source
63: MFC
64: valve
100: control device

1. A plasma processing device comprising:
a chamber accommodating a stage on which a substrate is placed;
an antenna disposed outside the chamber;
a dielectric window disposed between the chamber and the antenna;
a gas supply unit configured to supply a process gas into the chamber;
a power supply unit configured to supply high-frequency power to the antenna to supply high-frequency waves into the chamber through the dielectric window and generate plasma from the process gas in the chamber;
an electron generation unit configured to generate electrons in the chamber by excitation of the process gas supplied into the chamber; and
a control device configured to control the power supply unit so as to supply the high-frequency power to the antenna simultaneously with the start of the excitation of the process gas by the electron generation unit or after the excitation of the process gas by the electron generation unit is started.

2. The plasma processing device of claim 1, wherein the power supply unit supplies the high-frequency power from the antenna into the chamber to which the process gas is supplied to generate inductively coupled plasma in the chamber.

3. The plasma processing device of claim 1, wherein the electron generation unit applies a DC voltage to the process gas supplied into the chamber to generate DC discharge, and generates electrons in the chamber.

4. The plasma processing device of claim 3, wherein the dielectric window includes a first dielectric window and a second dielectric window,
a Faraday shield is disposed between the first dielectric window and the second dielectric window, and
the electron generation unit applies the DC voltage to the Faraday shield to generate DC discharge in the chamber.

5. The plasma processing device of claim 3, wherein the electron generation unit applies the DC voltage to the stage to generate DC discharge in the chamber.

6. The plasma processing device of claim 3, wherein the electron generation unit superimposes the DC voltage on the high-frequency power supplied to the antenna to generate DC discharge in the chamber.

7. The plasma processing device of claim 3, wherein the control device controls the electron generation unit such that a DC voltage is repeatedly applied to the process gas at predetermined time intervals until plasma is generated from the process gas in the chamber.

8. The plasma processing device of claim 7, wherein the control device controls the electron generation unit such that a magnitude of the DC voltage applied to the process gas at the predetermined time intervals gradually increases until plasma is generated from the process gas in the chamber.

9. The plasma processing device of claim 8, wherein the control device controls the electron generation unit such that the magnitude of the DC voltage gradually increases from a voltage which is lower by a predetermined voltage than a magnitude of a DC voltage at the time of previous generation of the process gas in the chamber.
